(19) United States
(12) Patent Application Publication
(10) Pub. No.: US 2014/0085964 A1
(43) Pub. Date: Mar. 27, 2014

(54) SEMICONDUCTOR STORAGE DEVICE

(71) Applicants: ELPIDA MEMORY, INC., Tokyo (JP); SHARP KABUSHIKI KAISHA, Osaka (JP)

(72) Inventors: Takashi NAKANO, Osaka (JP); Yukiko TAMAI, Osaka (JP); Kenji MAE, Tokyo (JP)

(73) Assignees: ELPIDA MEMORY, INC., Tokyo (JP); SHARP KABUSHIKI KAISHA, Osaka (JP)

(21) Appl. No.: 14/028,942

(22) Filed: Sep. 17, 2013

(30) Foreign Application Priority Data
Sep. 21, 2012 (JP) 2012-208579

(51) Int. Cl. G11C 13/00

(52) U.S. Cl. CPC G11C 13/004
USPC 365/148

(57) ABSTRACT

A control circuit controls memory operations such that, in a first rewriting operation in which a resistance state of a variable resistance element is changed from a first state to a second state, a first voltage pulse is applied to both terminals of a memory cell while limiting the amount of current flowing through the variable resistance element to a value smaller than or equal to a certain small amount of current, in a second rewriting operation in which the resistance state of the variable resistance element is changed from the second state to the first state, a second voltage pulse is applied to both terminals of the memory cell, and, in a reading operation in which the resistance state stored in the variable resistance element is read, a third voltage pulse is applied to both terminals of the memory cell.

### CROSS REFERENCE TO RELATED APPLICATION

This Nonprovisional application claims priority under 35 U.S.C. §119(a) on Patent Application No. 2012-208579 filed in Japan on 21 Sep. 2012 the entire contents of which are hereby incorporated by reference.

### BACKGROUND OF THE INVENTION

1. Field of the Invention

The present invention relates to a non-volatile semiconductor storage device that stores information using variable resistance elements, each of which is configured by a variable resistor composed of a metal oxide or a metal oxynitride and a first electrode and a second electrode that sandwich the variable resistor.

2. Description of the Related Art

Non-volatile semiconductor storage devices typified by flash memories are being used in various apparatuses such as computers, communication apparatuses, measuring apparatuses, automatic control apparatuses, and domestic appliances for personal use as large-capacity, small-size information recording media, and there have been strong demands for non-volatile semiconductor storage devices whose capacity is larger and that are offered at lower prices. This is because non-volatile semiconductor storage devices are electrically rewritable and data stored therein is not erased even if power is no longer supplied thereto, and accordingly may be used in highly portable memory cards, mobile electronic devices such as mobile phones, data storage apparatuses for storing operation setting values of other apparatuses in a non-volatile manner, program storage apparatuses, and the like.

Some non-volatile semiconductor storage devices composed of new materials have been proposed in recent years, and a resistive random-access memory (RRAM; registered trademark) is especially prominent among such non-volatile semiconductor storage devices. The memory function of the RRAM is realized using variable resistance elements whose resistances change when current larger than read current flows through the variable resistance elements, and the RRAM is considered promising because the RRAM excels in processing speed, capacity, power consumption, and the like.

In Japanese Patent No. 4195715, a semiconductor storage device including one or a plurality of memory cell arrays in which a plurality of non-volatile memory cells including variable resistance elements are arranged in a row direction and a column direction and a plurality of word lines and a plurality of bit lines are arranged in the row direction and the column direction, respectively, in order to enable section of a certain memory cell or a certain memory cell group is disclosed as an example of the RRAM. In Japanese Patent No. 4195715, a material such as an oxide having a perovskite structure containing manganese or an oxide or an oxynitride of an element selected from titanium, nickel, vanadium, zirconium, tungsten, cobalt, zinc, iron, and copper, the material being sandwiched between two electrodes, is disclosed as an example of the variable resistance element.

In an example of the configuration of each memory cell used in the RRAM, one end of a variable resistance element that stores information in accordance with a change in electrical resistance and a source (or a drain) of a selection transistor are connected to each other, either another end of the variable resistance element or the drain (or the source) of the selection transistor is connected to a common bit line in the column direction, the other is connected to a source line in common, and a gate of the selection transistor is connected to a common word line in the row direction in a memory cell array. In such a configuration, by applying voltages to the word lines, the bit lines, and the source lines connected to the memory cell array under certain application conditions, an operation for rewriting information stored in the memory cells and an operation for reading the information stored in the memory cells are realized.

In the rewriting operation, the electrical resistance of the variable resistance element changes between two or more resistance states in accordance with rewriting voltage applied between both ends of the variable resistance element. In the following description, two of such resistance states will be referred to as a “first resistance state”, which is a high-resistance state, and a “second resistance state”, which is a low-resistance state. In general, the absolute value of rewriting voltage (first rewriting voltage) necessary to change the electrical resistance of the variable resistance element from the first resistance state to the second resistance state is different from the absolute value of rewriting voltage (second rewriting voltage) necessary to change the electrical resistance of the variable resistance element from the second resistance state to the first resistance state. The first rewriting voltage is generally higher than the second rewriting voltage. On the other hand, the polarities of the first rewriting voltage and the second rewriting voltage may be the same or may be opposite depending on the configuration of the variable resistance element.

More specifically, in Japanese Patent No. 4195715, a memory cell array 4 has a configuration in which memory cells 1 are arranged in a matrix illustrated in FIG. 16. In FIG. 16, each memory cell 1 is configured by connecting one end of a variable resistance element 2 and a drain of a selection transistor 3 to each other, and another end of the variable resistance element 2 is connected to one of bit lines BL1 to BLn and a source of the selection transistor 3 is connected to a source line SL. A gate of the selection transistor 3 is connected to one of word lines WL1 to WLm extending in the row direction (horizontal direction in FIG. 16). That is, each memory cell 1 includes a series circuit configured by the variable resistance element 2 and the selection transistor 3. Therefore, the selection transistors 3 of memory cells 1 in rows that have not been selected are turned off (nonconductive) to block current paths through the variable resistance elements 2 of memory cells 1 other than a selected memory cell 1. Accordingly, a problem that the selected memory cell 1 is not correctly read due to the memory cells 1 that have not been selected connected to the same bit line BL during the reading operation may be avoided.

Furthermore, because bit line selection transistors 5 are inserted between the bit lines BL1 to BLn and the variable resistance elements 2, the variable resistance elements 2 of the memory cells 1 that have not been selected are electrically isolated from the bit line BL in a selected column to which a certain reading voltage is applied during the reading operation. Therefore, a problem of voltage stress applied to the variable resistance elements 2 is avoided, thereby achieving highly reliable data retention characteristics.

When the resistance state held by the variable resistance element 2 of a memory cell 1 is to be read in the memory cell array 4 illustrated in FIG. 16, the bit line selection transistor 5 connected to a selected bit line BL is caused to be conductive in order to apply the reading voltage to the selected bit line BL connected to the selected memory cell 1 to be read. At the same time, a selected word line WL connected to the gate of the selection transistor 3 of the selected memory cell 1 is set to a high level by a word line driver (row decoder) 6 in order to cause the selection transistor 3 to be conductive. In addition, reference voltage, that is, for example, a voltage of 0 V (ground voltage), is applied to a source line SL. As a result, a reading current path extending from the selected bit line BL to the source line SL though the selection transistor 3 and the variable resistance element 2 of the selected memory cell 1 is formed. On the other hand, with respect to the memory cells 1 that have not been selected, word lines WL that have not been selected are set to a low level, that is, for example, a voltage of 0 V, by the word line drivers 5, and bit lines BL that have not been selected are set to a low level, that is, for example, a voltage of 0 V or an open state (high-impedance state). Therefore, there are no current paths other than the reading current path through the variable resistance element 2 of the selected memory cell 1. As a result, only a change in the electrical resistance of the variable resistance element 2 of the selected memory cell 1 appears as a change in current flowing through the bit lines BL because of the above-described conditions of the voltages applied to the bit lines BL, the word lines WL, and the source lines SL, and by identifying the amount of current using a read circuit, information stored in the selected memory cell 1 may be accurately read.

Furthermore, since the variable resistance elements 2 of the memory cells 1 that have not been selected and the selected bit line BL are electrically isolated from each other, voltage stress from the bit lines BL is not directly applied to the variable resistance elements 2 of the memory cells 1 that have not been selected even if the reading operation is repeatedly performed on the same bit line BL. By determining the reading voltage to be applied to the variable resistance element 2 of the selected memory cell 1 as voltage having a polarity and magnitude with which voltage stress caused by the reading is hardly applied, a semiconductor storage device that significantly reduces changes in the resistance states of the other variable resistance elements 2 caused by voltage stress, that is, a possibility that stored data is accidentally erased, and that has improved reliability in data retention may be provided.

In Japanese Patent No. 4195715, the polarity of reading voltage pulses is the same as that of either the first rewriting voltage or the second rewriting voltage, whichever the absolute value of the voltage amplitude of voltage pulses is larger. It is claimed that, in doing so, a semiconductor storage device that significantly reduces the possibility that stored data is accidentally erased and whose reliability in data retention is improved may be provided.

### SUMMARY OF THE INVENTION

As a result of study, the inventors have found that when a variable resistance element composed of a metal oxide film is operated with a small drive current of 100 μA or less, the first rewriting voltage for establishing a low-resistance state in the variable resistance element needs to be applied for a longer period than the second rewriting voltage for establishing a high-resistance state in the variable resistance element, but the absolute value of voltage pulses may be smaller.

Therefore, first and second rewriting operations may be performed while setting the absolute value of the voltage pulses of the first rewriting voltage to be smaller than or equal to the absolute value of voltage pulses of the second rewriting voltage. That is, when drive current becomes smaller, the first and second rewriting operations may be performed even if the absolute values of the first and second rewriting voltage pulses applied in the first and second rewriting operations, respectively, are the same.

However, when the absolute values of the first and second rewriting voltage pulses applied in the first and second rewriting operations, respectively, are the same, it is difficult to uniquely determine the polarity of the reading voltage pulses to be applied in the reading operation on the basis of the technique disclosed Japanese Patent No. 4195715. Depending on the polarity of the reading voltage pulses, the resistance states of the variable resistance elements can change and accordingly stored data can be erased, which poses a problem in that the reliability in data retention decreases.

In view of the above problem, an object of the present invention is to provide a semiconductor storage device that significantly reduces the possibility that stored data is accidentally erased when the reading operation is repeatedly performed on the same memory cell including the variable resistance element, thereby significantly improving the data retention characteristics.

In order to solve the above problem, a semiconductor storage device according to a first characteristic of the present invention includes a variable resistance element that is used for storing information and that includes a variable resistor composed of a metal oxide or a metal oxynitride and a first electrode and a second electrode that sandwich the variable resistor, electrical resistance between both electrodes of the variable resistance element changing in accordance with electrical stress applied between both electrodes. In a first rewriting operation in which a resistance state of the variable resistance element is changed from a first state to a second state, which is a low-resistance state, a first voltage pulse whose absolute value of voltage amplitude is a first voltage and that has a first polarity is applied to both terminals of a memory cell including the variable resistance element. In a second rewriting operation in which the resistance state of the variable resistance element is changed from the second state to the first state, which is a high-resistance state, a second voltage pulse whose absolute value of voltage amplitude is a second voltage, that has a second polarity, which is opposite the first polarity, and whose application time is shorter than application time of the first voltage pulse is applied to both terminals of the memory cell. In a reading operation in which the resistance state stored in the variable resistance element is read, a third voltage pulse that has the first polarity and whose absolute value of voltage amplitude is smaller than the absolute value of the voltage amplitude of the first voltage is applied to both terminals of the memory cell.

According to the semiconductor storage device according to the first characteristic, a semiconductor storage device whose data retention characteristics are significantly improved may be provided by performing the reading operation while applying the third voltage pulse whose polarity is the same as that of either the first voltage pulse applied in the first rewriting operation or the second voltage pulse applied in the second rewriting operation, whichever the application time of pulses is longer.

In the semiconductor storage device according to the first characteristic of the present invention, in the first rewriting operation, the first voltage pulse is preferably applied to both terminals of the memory cell while limiting an amount of current flowing through the variable resistance element to a value smaller than or equal to a certain small amount of current. In the second rewriting operation, the second voltage pulse is preferably applied to both terminals of the memory cell while allowing an amount of current larger than the certain small amount of current to flow into the variable resistance element.

Furthermore, in the semiconductor storage device according to the first characteristic of the present invention, the certain small amount of current is preferably smaller than or equal to 100 μA.

Furthermore, in the semiconductor storage device according to the first characteristic of the present invention, the second voltage is a voltage equal to or higher than the first voltage.

Furthermore, in the semiconductor storage device according to the first characteristic of the present invention, the second voltage is the same as the first voltage.

According to a second characteristic of the present invention, in the semiconductor storage device according to the first characteristic of the present invention, the memory cell is configured by connecting either the first electrode or the second electrode of the variable resistance element and one terminal of a pair of input and output terminals of a selection transistor to each other. The semiconductor storage device according to the second characteristic of the present invention further includes a memory cell array that includes a plurality of memory cells, each of which is the foregoing memory cell, are arranged at least in a row direction or in a column direction, a control circuit that selects one or a plurality of memory cells from the memory cell array and that controls the first rewriting operation, the second rewriting operation, and the reading operation performed on a variable resistance element of the selected one or plurality of memory cells, and a voltage application circuit that applies necessary voltages to both terminals of the selected one or plurality of memory cells and a control terminal of the selection transistor of the selected one or plurality of memory cells in the first rewriting operation, the second rewriting operation, and the reading operation.

According to the semiconductor storage device according to the second characteristic, information stored in the one or plurality of selected memory cells may be accurately read in the reading operation by configuring the memory cell array using memory cells in each of which the variable resistance element and the selection transistor are connected in series with each other.

Furthermore, since the amount of current flowing through the variable resistance element in the first rewriting operation may be limited to the certain small amount of current by the voltage applied to the control terminal of the selection transistor, a semiconductor storage device that operates with the small amount of current and whose power consumption is small may be easily realized.

According to a third characteristic of the present invention, in the semiconductor storage device according to the second characteristic of the present invention, in the first rewriting operation, the voltage application circuit applies a voltage higher than ground voltage by the first voltage to one terminal of the selected one or plurality of memory cells and the ground voltage to the other terminal. In the second rewriting operation, the voltage application circuit applies the ground voltage to the one terminal of the selected one or plurality of memory cells and a voltage higher than the ground voltage by the second voltage to the other terminal.

According to the semiconductor storage device according to the third characteristic, since positive and negative voltage pulses may be applied to both terminals of the selected one or plurality of memory cells by generating the positive voltage relative to the ground voltage using a voltage generation circuit, the voltage generation circuit need not generate the negative voltage. Therefore, the configuration of the voltage generation circuit may be simplified.

At this time, by determining the absolute value (first voltage) of voltage amplitude of the voltage pulses applied in the first rewriting operation to be the same as the absolute value (second voltage) of voltage amplitude of the voltage pulses applied in the second rewriting operation, the voltage to be generated by the voltage generation circuit may be reduced.

In the semiconductor storage device according to the second or third characteristic of the present invention, in the memory cell array, one terminals of memory cells in the same column on a side of variable resistance elements are preferably connected to a bit line extending in the column direction. Control terminals of the selection transistors of memory cells in the same row are preferably connected to a word line extending in the row direction. The other terminals of the memory cells on a side of the selection transistors are preferably connected to a source line extending in the row direction or the column direction. The first voltage pulse is preferably a positive voltage pulse relative to voltage of the source line connected to the selected one or plurality of memory cells. The second voltage pulse is preferably a negative voltage pulse relative to the voltage of the source line connected to the selected one or plurality of memory cells.

In the semiconductor storage device according to the second or third characteristic of the present invention, the selection transistors may be n-channel metal-oxide-semiconductor field-effect transistors. In this case, special transistors for the memory cells need not be used as the selection transistors and the selection transistors may be manufactured by the same process as one for manufacturing n-channel metal-oxide-semiconductor field-effect transistors (MOSFETs) that are generally used in peripheral circuits of the semiconductor storage device. Therefore, a process for manufacturing the semiconductor storage device may be simplified, which contributes to reduction in manufacturing cost.

As described above, according to the present invention, by determining the polarity of the voltage pulses applied in the reading operation to be same as the polarity of either the voltage pulses applied in the first rewriting operations or the voltage pulses applied in the second rewriting operation, whichever the application time of pulses is shorter, a semiconductor storage device that significantly reduces the possibility that stored data is accidentally erased when the reading operation is repeatedly performed on the same memory cell and whose data retention characteristics are significantly improved may be provided.

### BRIEF DESCRIPTION OF THE DRAWINGS

FIG. 1 is a circuit block diagram schematically illustrating the configuration of a semiconductor storage device according to an embodiment of the present invention.

FIG. 2 is a circuit diagram illustrating an example of a memory cell array of the semiconductor storage device.

FIG. 3 is a diagram illustrating an example of the planar layout of the memory cell array of the semiconductor storage device.

FIG. 4 is a cross-sectional view of the structure of the memory cell array of the semiconductor storage device.

FIG. 5 is a diagram illustrating an example of conditions of voltages applied to both terminals of a selected memory cell at a time when a first rewriting operation (setting operation) is performed.

FIG. 6 is a diagram illustrating an example of conditions of voltages applied to both terminals of the selected memory cell at a time when a second rewriting operation (reset operation) is performed.

FIG. 7 is a diagram illustrating an example of conditions of voltages applied to both terminals of the selected memory cell at a time when a reading operation is performed.

FIG. 8 is a graph illustrating an example of the switching characteristics of a variable resistance element during application of direct current (DC) voltage.

FIG. 9 is a graph illustrating an example of the switching characteristics of the variable resistance element during application of pulse voltage.

FIGS. 10A and 10B are graphs illustrating the reading disturbance characteristics of the variable resistance element that depend on the polarity of the reading voltage pulses.

FIG. 11 is a graph illustrating a relationship between resistance after a change, application time of voltage pulses, and drive current for a selection transistor in the first rewriting operation.

FIG. 12 is a graph illustrating a relationship between the resistance after the change, the voltage of the applied voltage pulses, and the application time of the voltage pulses in the first rewriting operation.

FIG. 13 is a graph illustrating a relationship between the drive current for the selection transistor and the application time of the pulses necessary for the first and second rewriting operations.

FIG. 14 is a diagram illustrating conditions of voltages applied to each memory cell in the memory cell array at a time when the first rewriting operation is collectively performed on a plurality of memory cells.

FIG. 15 is a diagram illustrating conditions of voltages applied to each memory cell in the memory cell array at a time when the first rewriting operation is collectively performed on the plurality of memory cells.

FIG. 16 is a diagram illustrating an example the configuration of a memory cell array of a semiconductor storage device in an example of the related art.

### DESCRIPTION OF THE PREFERRED EMBODIMENTS

### First Embodiment

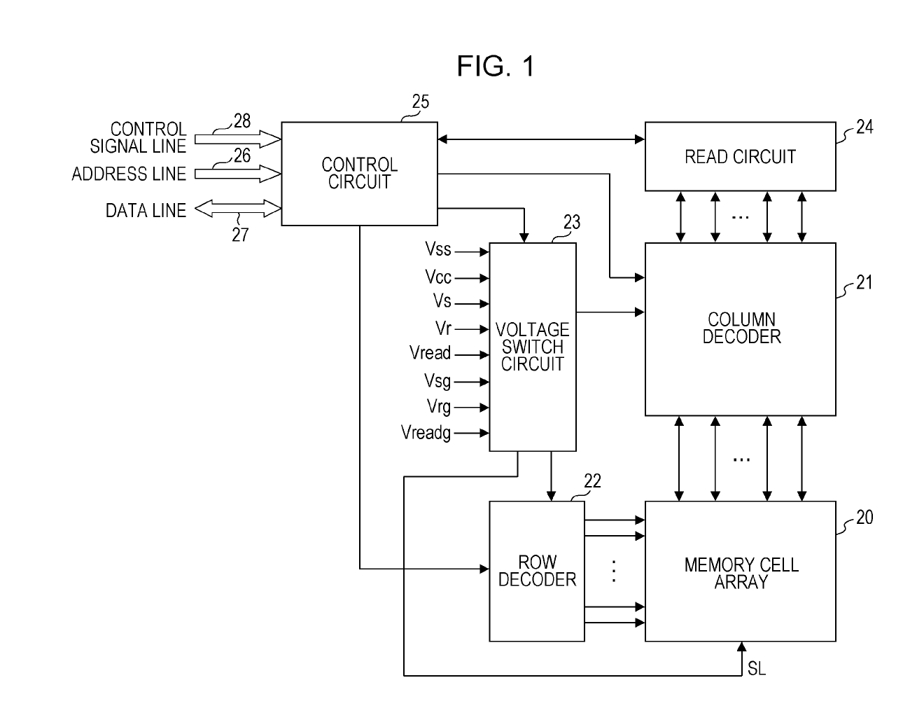

FIG. 1 illustrates a circuit block diagram schematically illustrating the configuration of a semiconductor storage device (hereinafter referred to as a “device in the present invention”) according to an embodiment of the present invention. The device in the present invention illustrated in FIG. 1 includes a memory cell array 20, a column decoder 21, a row decoder 22, a voltage switch circuit (voltage generation circuit) 23, a read circuit 24, and a control circuit 25.

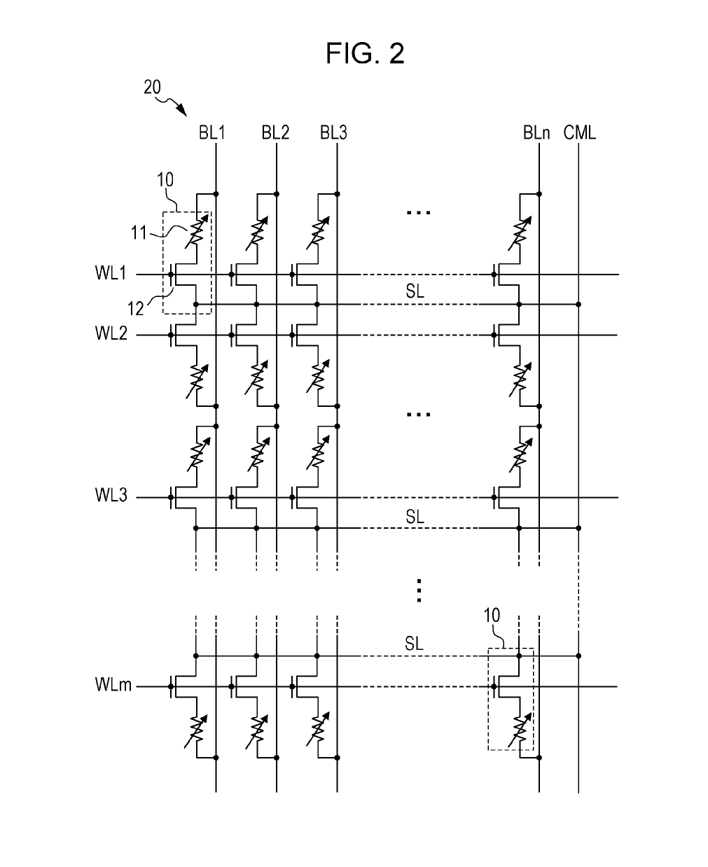

FIG. 2 illustrates an example of the circuit configuration of the memory cell array 20 illustrated in FIG. 1. As illustrated in FIG. 2, the memory cell array 20 includes a plurality of memory cells 10 arranged in a row direction and a column direction, each of the memory cells 10 including a variable resistance element 11 and a selection transistor 12 connected in series with each other so as to have a pair of input and output terminals.

In FIG. 2, one terminal of the pair of input and output terminals of each memory cell 10 in the same column is connected, on the side of the variable resistance element 11, commonly to one of a plurality of bit lines BL1 to BLn (n in a natural number) extending in the column direction (vertical direction in FIG. 2). The other terminal of the pair of input and output terminals of each memory cell 10 in the same row is connected, on the side of the selection transistor 12, commonly to one of source lines SL extending in the row direction (horizontal direction in FIG. 2). The source lines SL are connected to a common line CML extending in the column direction. On the other hand, control terminals of the selection transistors 12 of the memory cells 10 in the same row are connected to a sole or one of a plurality of word lines WL1 to WLm extending in the row direction. Each selection transistor 12 is a metal-oxide-semiconductor field-effect transistor (MOSFET) that is of the same type as ones included in peripheral circuits of the memory cell array 20, which will be described later, and is an enhancement-mode n-channel MOSFET whose threshold voltage is positive (for example, +0.1 V to +1.0 V; preferably about +0.5 V).

In a general MOSFET, one of two impurity diffusion regions that face each other through a gate electrode serves as a drain and the other serves as a source, but which of the two impurity diffusion regions serves as the drain or the source is determined in accordance with the circuit configuration. In the device in the present invention, one of the two impurity diffusion regions located close to a bit line is determined as the drain, and the other of the two impurity diffusion regions located close to a source line SL is determined as the source for the sake of convenience, but the essence of the present invention is not affected even if the roles of the two impurity diffusion regions are reversed.

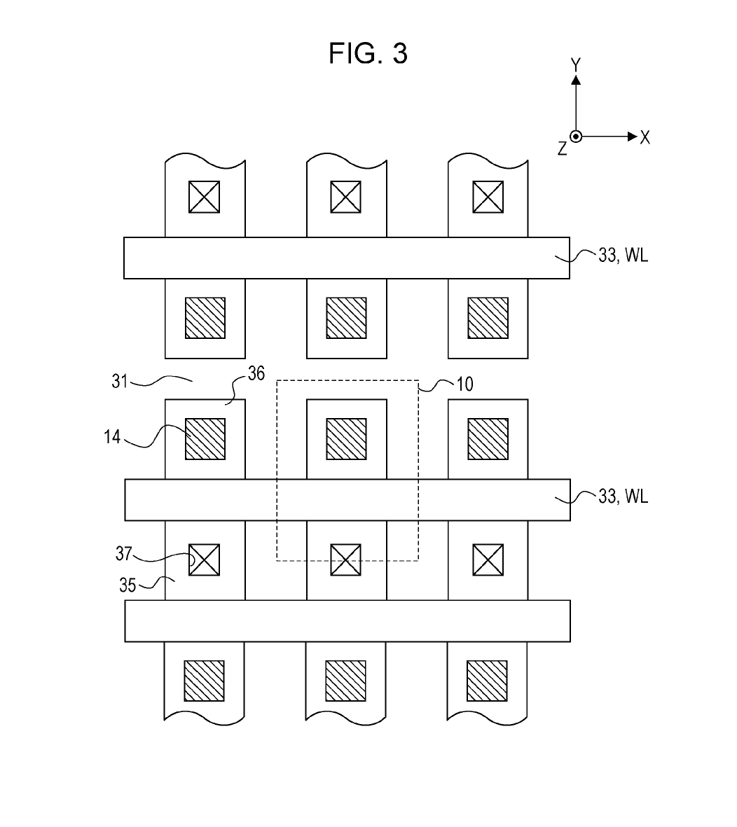

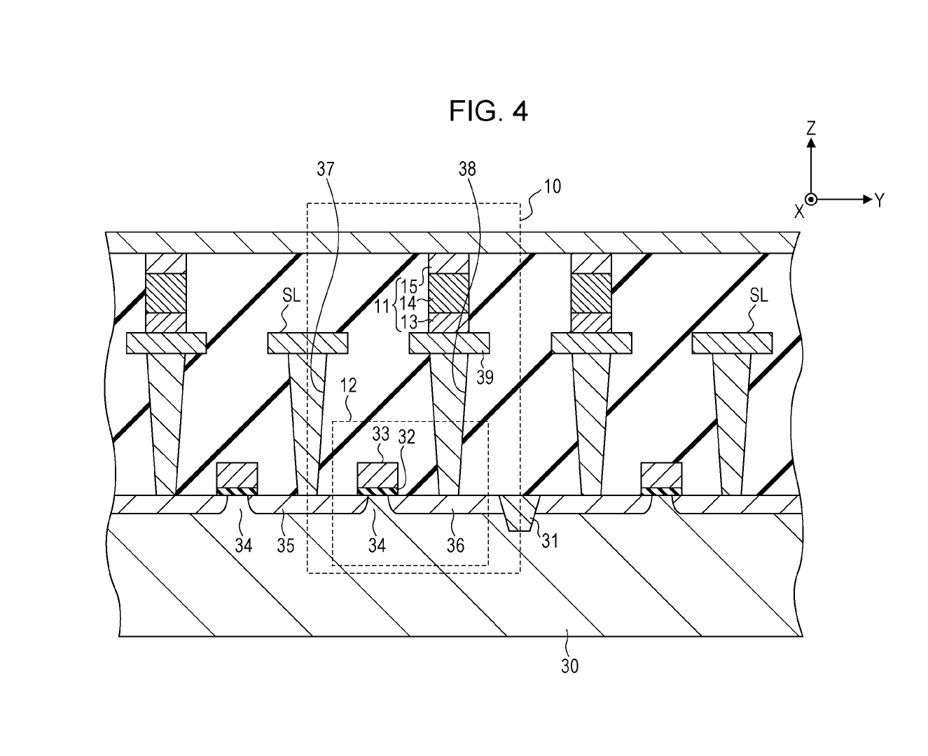

FIG. 3 schematically illustrates a typical planar layout of the structure of the memory cell array 20 illustrated in FIG. 2, and FIG. 4 is a typical cross-sectional view of the memory cell array 20 taken along a plane perpendicular to a semiconductor substrate. X, Y, and Z directions illustrated in FIGS. 3 and 4 for the sake of convenience represent the row direction, the column direction, and a direction perpendicular to a surface of the semiconductor substrate, respectively. FIG. 4 is a cross-sectional view taken along a YZ plane. In the planar layout illustrated in FIG. 3, the source lines SL extending in the row direction (X direction) and the bit lines BL (BL1 to BLn) extending in the column direction (Y direction) are omitted in order to show a structure therebelow.

As illustrated in FIGS. 3 and 4, at least part of a p-type semiconductor substrate (or a p-type well) 30 is used as an active region isolated by an element isolation film 31 through, for example, shallow trench isolation (STI) or the like. Gate insulation films 32 are formed in at least part of the active region, and gate electrodes 33 composed of, for example, polycrystalline silicon are formed in such a way as to cover at least part of the gate insulation films 32. Thus, channel regions 34 are formed under the gate insulation films 32, and the selection transistors 12 are formed whose sources and drains are impurity diffusion layers 35 and 36, respectively, that sandwich the channel regions 34 and whose conductivity type is opposite (n-type) that of the semiconductor substrate 30. The gate electrodes 33 of the selection transistors 12 are connected to one another in memory cells 10 adjacent to one another in the row direction (X direction) to configure the word lines WL (WL1 to WLm).

The impurity diffusion layers (sources) 35 are connected, through contact holes 37 that penetrate interlayer insulation films and that are filled with a conductive material, to the source lines SL extending in the row direction (X direction). Similarly, the impurity diffusion layers (drains) 36 are connected, through contact holes 38, to a metal wire layer 39 formed as an island, and an upper surface of the metal wire layer 39 is connected to lower electrodes 13 of the variable resistance elements 11. Upper electrodes 15 of the variable resistance elements 11 are connected to the bit lines BL (BL1 to BLn) extending in the column direction (Y direction), thereby connecting the memory cell 10 adjacent to one another in the column direction (Y direction) to one another.

Each variable resistance element 11 is an element in which a variable resistor composed of a metal oxide or a metal oxynitride is sandwiched between a first electrode and a second electrode, and electrical resistance between the first electrode and the second electrode changes in accordance with electrical stress applied between the first electrode and the second electrode. As illustrated in FIG. 4, a general structure of each variable resistance element 11 is a three-layer structure in which the lower electrode 13, a variable resistor 14, and the upper electrode 15 are stacked in this order. However, the structure of each variable resistance element 11 is not limited to this insofar as the electrical resistance thereof changes between a first state and a second state by applying electrical stress between the electrodes thereof as described above.

In this embodiment, as a material used for each variable resistor 14, for example, a hafnium oxide (HfOx), a zirconium oxide (ZrOx), a titanium oxide (TiOx), a tantalum oxide (TaOx), a tungsten oxide (WOx), an aluminum oxide (AlOx), a hafnium oxynitride (HfOxNy), a zirconium oxynitride (ZrOxNy), a titanium oxynitride (TiOxNy), a tantalum oxynitride (TaOxNy), a tungsten oxynitride (WOxNy), an aluminum oxynitride (AlOxNy), or the like that has an affinity with semiconductor processing is assumed to be used. Alternatively, an oxide or an oxynitride of a transition metal element selected from nickel (Ni), vanadium (V), cobalt (Co), zinc (Zn), iron (Fe), and copper (Cu) may be used. However, the present invention is not limited to these. As described above, the material of each variable resistance element 11 is not particularly limited insofar as the electrical resistance between the electrodes of each variable resistance element 11 changes in accordance with electrical stress applied between the electrodes.

When each variable resistance element 11 is to be configured while using one of the above-mentioned metal oxides and metal oxynitrides as the variable resistor 14, a current path (filament) through which resistance switching occurs needs to be formed in the variable resistor 14 before use by applying, to each variable resistance element 11, voltage pulses whose voltage amplitude and pulse width are larger than those of voltage pulses used in a normal rewriting operation, in order to establish, in each variable resistance element 11 in an initial state immediately after manufacture, a state (variable resistance state) in which each variable resistance element 11 may switch between a high-resistance state and a low-resistance state in accordance with applied electrical stress. Such a process for applying voltage is called a “forming process”. It is known that a filament formed by the forming process determines the resultant electrical characteristics (switching characteristics) of each variable resistance element 11.

As the material of the first electrode (lower electrode) 13 and the second electrode (upper electrode) 15 sandwiching the variable resistor 14, for example, a metal material composed of Ti, Ta, Hf, Zr, TiN, Pt, Ru, or W or a conductive oxide such as a RuO₂, IrO₂, or an indium tin oxide (ITO) may be used. As described above, the shapes and the materials of the two electrodes are not particularly limited insofar as the electrical resistance between the electrodes changes in accordance with electrical stress applied between the electrodes. However, the above-described materials are preferable because desirable characteristics may be obtained.

In particular, it is considered that a change in resistance is caused in an interface between an electrode whose potential barrier is higher and work function is larger and the metal oxide or the metal oxynitride. Therefore, it is desirable that either the first electrode or the second electrode is composed of a conductive material whose work function is large and is in Schottky contact with the variable resistor 14, and the other electrode is composed of a conductive material whose work function is small and is in ohmic contact with the variable resistor 14. By using such a configuration, each variable resistance element 11 is known to perform stable resistance switching. More specifically, when the work function of the first electrode is larger than that of the second electrode, it is preferable that the first electrode is composed of a conductive material (e.g., Ti, Ta, Hf, Zr, or the like) having a work function smaller than 4.5 eV, and the second electrode is composed of a conductive material (e.g., Pt, TiN, Ru, RuO₂, ITO, or the like) having a work function equal to or larger than 4.5 eV.

In this embodiment, each variable resistance element 11 is assumed to be a so-called bipolar element, in which the polarity of voltage pulses applied to change the resistance state to the low-resistance state is opposite that of voltage pulses applied to change the resistance state to the high-resistance state.

In the memory cell array 20, when one of the memory cells 10 that has been selected as an operation target (hereinafter referred to a “selected memory cell 10” as necessary) is to be rewritten, a selection state is established by applying voltage to a word line WL connected to the selected memory cell 10, and then a certain voltage is applied to a bit line BL and a source line SL connected to the selected memory cell 10 so that a certain rewriting voltage is applied to both terminals of the selected memory cell 10. Here, in a first rewriting operation (setting operation) in which the resistance state of the variable resistance element 11 is changed to the low-resistance state, a certain first voltage is applied between the bit line BL and the source line SL connected to the selected memory cell 10 so that setting voltage pulses having a first polarity are applied to both terminals of the selected memory cell 10, thereby changing the resistance state of the variable resistance element 11 of the selected memory cell 10 to the low-resistance state. On the other hand, in a second rewriting operation (resetting operation) in which the resistance state of the variable resistance element 11 is changed to the high-resistance state, a certain second voltage is applied between the bit line BL and the source line SL connected to the selected memory cell 10 so that reset voltage pulses having a second polarity, which is opposite the first polarity, are applied to both terminals of the selected memory cell 10, thereby changing the resistance state of the variable resistance element 11 of the selected memory cell 10 to the high-resistance state.

At this time, the setting operation is performed while limiting the amount of current flowing through the variable resistance element 11 of the selected memory cell 10 to a certain small amount of current. In doing so, a small filament is formed, which reduces variation in resistance in the low-resistance state. Therefore, in the setting operation, voltage with which the amount of current flowing through the variable resistance element 11 can be limited to the certain small amount of current by the selection transistor 12 is applied to the word line WL connected to the selected memory cell 10.

In contrast, in the reset operation, the amount of current flowing through the variable resistance element 11 of the selected memory cell 10 need not be limited. On the contrary, the selected memory cell 10 operates at higher speed when the amount of current is not limited. Therefore, in the reset operation, voltage with which the selection transistor 12 is turned on is applied to the word line WL connected to the selected memory cell 10. More preferably, a certain high voltage is applied to the word line WL so that the selection transistor 12 does not limit the amount of current.

In FIG. 1, the control circuit 25 controls memory operations including rewriting of a selected memory cell 10 in the memory cell array 20 (the first writing operation and the second rewriting operation) and reading of the selected memory cell 10 in the memory cell array 20. More specifically, the control circuit 25 controls the memory operations performed on each memory cell 10 by controlling the column decoder 21, the row decoder 22, and the voltage switch circuit 23 on the basis of an address signal 26 input from an address line, a data input signal 27 input from a data line, and a control input signal 28 input from a control signal line. In the example illustrated in FIG. 1, the control circuit 25 has functions of a general address buffer circuit, a data input/output buffer circuit, and a control input buffer circuit, which are not illustrated.

In the memory operations including the reading operation, the first rewriting operation (setting operation), and the second rewriting operation (reset operation) performed on the memory cell array 20, the voltage switch circuit (voltage generation circuit) 23 switches voltages applied to the word lines WL (a selected word line and word lines that have not been selected), the bit lines BL (a selected bit line and bit lines that have not been selected), and the source lines SL necessary for the memory operations in accordance with the memory operations, and supplies the voltages to the memory cell array 20 through the column decoder 21 and the row decoder 22. More specifically, the voltages applied to the selected word line WL and the word lines WL that have not been selected are supplied from the voltage switch circuit 23 through the row decoder 22, and the voltages supplied to the selected bit line BL and the bit lines BL that have not been selected are supplied from the voltage switch circuit 23 through the column decoder 21. The voltages applied to the source lines SL are directly supplied to the source lines SL from the voltage switch circuit 23. FIG. 1 illustrates power supply voltage Vcc of the device in the present invention, ground voltage Vss, read voltage Vread, voltage Vs supplied to perform the setting operation (the absolute value of the first voltage applied to both terminals of the selected memory cell 10), voltage Vr supplied to perform the reset operation (the absolute value of the second voltage applied to both terminals of the selected memory cell 10), selected word line voltage Vreadg for the reading operation, selected word line voltage Vrg for the reset operation, and selected word line voltage Vsg for the setting operation. In this embodiment, the voltage Vr supplied to perform the reset operation, the voltage Vs supplied to perform the setting operation, the selected word line voltage Vreadg for the reading operation, and the selected word line voltage Vrg for the reset operation, and may be used in common. That is, in FIG. 1, each input voltage of the voltage switch circuit 23 is generalized.

Prior to the memory operations including the reading operation, the first rewriting operation (setting operation), and the second rewriting operation (reset operation) performed on the memory cell array 20, the column decoder 21 and the row decoder 22 select a memory cell corresponding to an address input from the address line 26 to the control circuit 25 as a memory cell to be subjected to the memory operations. In a normal reading operation, the row decoder 22 selects a word line WL in the memory cell array 20 corresponding to an address signal input from the address line 26, and the column decoder 21 selects a bit line BL in the memory cell array 20 corresponding to the address signal. In the setting operation, the reset operation, and verification operations (reading operations for verifying the storage states of the memory cells 10 after the setting operation and the reset operation), the row decoder 22 selects one or a plurality of word lines WL in the memory cell array 20 corresponding to a row address(es) specified by the control circuit 25, and the column decoder 21 selects one or a plurality of bit lines BL in the memory cell array 20 corresponding to a column address(es) specified by the control circuit 25.

As a result, in the memory operations, the column decoder 21 applies selected bit line voltage and non-selected bit line voltage to the selected bit line and the bit lines that have not been selected, respectively. Similarly, in the memory operations, the row decoder 22 applies selected word line voltage and non-selected word line voltage to the selected word line WL and the word lines WL that have not been selected, respectively.

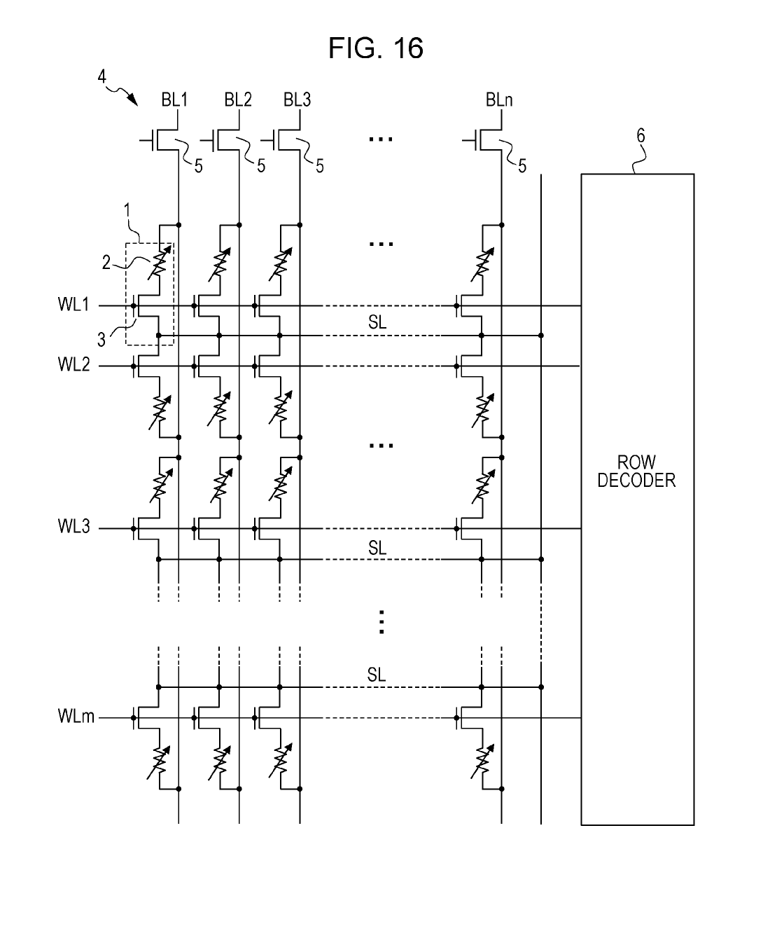

The column decoder 21 is provided with transistors (corresponding to bit line selection transistors 5 illustrated in FIG. 16) with respect to each of the bit lines BL1 to BLn. In each of the transistors, one terminal of a pair of input and output terminals is connected to one of the bit lines BL1 to BLn. The selected bit line voltage or the non-selected bit line voltage may be applied through the other terminals of the transistors.

In the reading operation, the read circuit 24 determines the state (resistance state) of stored data by comparing read current flowing from the bit line BL selected by the column decoder 21 to the source line SL through the selected memory cell 10 or a voltage value obtained by converting the read current with, for example, reference current or reference voltage, respectively. The read circuit 24 then transfers a result to the control circuit 25, and the result is output to the data line 27.

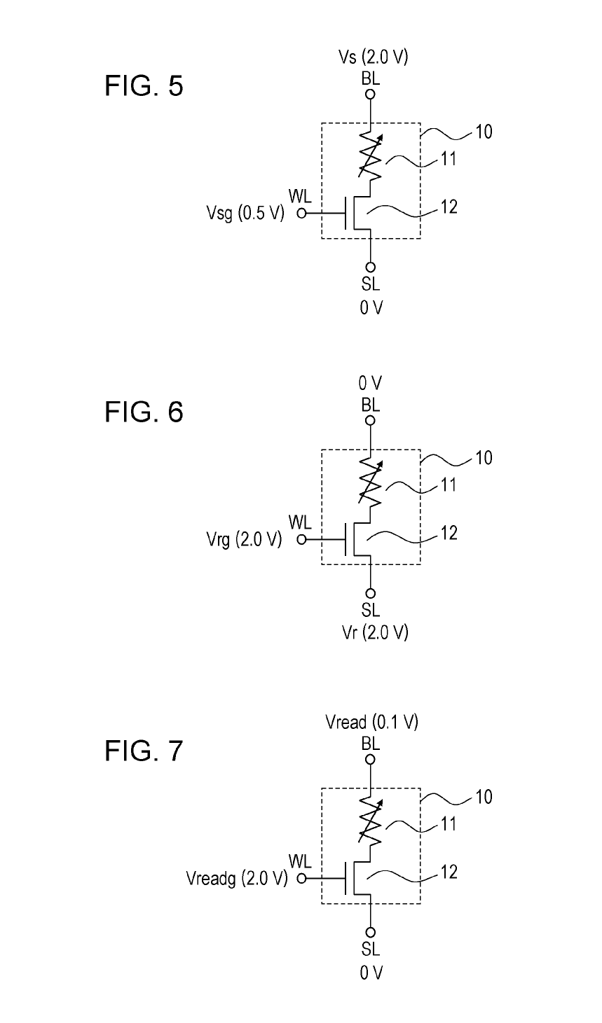

More specifically, FIG. 5 illustrates conditions of voltages applied to a certain memory cell 10 at a time when the certain memory cell 10 in the memory cell array 20 has been selected and is to be subjected to the first rewriting operation (setting operation). In the setting operation, for example, a voltage of 0 V (ground voltage) is applied to the source line SL of the memory cell 10 and voltage pulses of +2.0 V are applied to the selected bit line BL as the voltage Vs for 1 μs. For example, a voltage of +0.5 V, which is higher than a threshold voltage Vth of the selection transistor 12, is applied to the selected word line WL as the voltage Vsg. Since the selection transistor 12 is an n-channel MOSFET, current hardly flows into the variable resistance element 11 in the high-resistance state. Therefore, the voltage of 0 V applied to the source line SL is directly output to the drain (the lower electrode 13 of the variable resistance element 11) of the selection transistor 12, and accordingly the positive voltage Vs (+2.0 V) relative to the voltage of the lower electrode 13 is applied between both ends of the variable resistance element 11. Here, the application of the selected word line voltage Vsg and the selected bit line voltage Vs may begin in any order and end in any order.

As a result, a current path extending from the bit line BL to the source line SL is formed, and the electrical resistance of the variable resistance element 11 changes from the high-resistance state (first state) to the low-resistance state (second state). That is, in the device in the present invention, the first rewriting operation (setting operation) may be performed on the selected memory cell 10 by applying positive first voltage pulses relative to the voltage of the source line SL between both terminals of the selected memory cell 10.

The voltage to be applied to the selected source line SL need not be 0 V, and may vary in the range of ±0.1 V. By giving the same variation to the voltage Vs to be applied to the bit line BL, the rewriting voltage applied between both terminals of the selected memory cell 10 remains the same. However, the ground voltage of 0 V, which is the same as the voltage of peripheral circuits of the device in the present invention, is preferably used as the voltage to be applied to the selected source line SL.

On the other hand, FIG. 6 illustrates conditions of voltages applied to a certain memory cell 10 at a time when the certain memory cell 10 in the memory cell array 20 has been selected and is to be subjected to the second rewriting operation (reset operation). In the reset operation, for example, a voltage of +2.0 V is applied to the source line SL as the voltage Vr and a voltage of 0 V (ground voltage) is applied to the selected bit line BL for 20 ns. Other bit lines BL that have not been selected are in a floating state (high-impedance state). For example, a voltage of +2.0 V, which is higher than the threshold voltage Vth of the selection transistor 12, is applied to the selected word line WL as the voltage Vrg. In doing so, a current path extending from the source line SL to the bit line BL is formed, and the electrical resistance of the variable resistance element 11 changes from the low-resistance state (second state) to the high-resistance state (first state). That is, in the device in the present invention, the second rewriting operation may be performed by applying negative second voltage pulses relative to the voltage of the source line SL between both terminals of the selected memory cell 10. Here, the application of the selected word line voltage Vrg and the selected source line voltage Vr may begin in any order and end in any order.

The voltage to be applied to the selected bit line BL need not be 0 V, and may vary in the range of ±0.1 V. By giving the same variation to the voltage Vr to be applied to the source line SL, the rewriting voltage applied between both terminals of the selected memory cell 10 remains the same. However, the ground voltage of 0 V, which is the same as the voltage of the peripheral circuits of the device in the present invention, is preferably used as the voltage to be applied to the selected bit line BL.

Furthermore, FIG. 7 illustrates conditions of voltages applied to a certain memory cell 10 at a time when the certain memory cell 10 in the memory cell array 20 has been selected and is to be subjected to the reading operation. In the reading operation, voltage pulses whose polarity is the same as that of the voltage pulses applied in the first rewriting operation and whose absolute value of voltage amplitude is smaller than that of the voltage pulses applied in the first rewriting operation are applied to both terminals of the memory cell 10. For example, a voltage of 0 V (ground voltage) is applied to the selected source line SL, and a voltage of +0.1 V is applied to the selected bit line BL as the read voltage Vread. Other bit lines BL that have not been selected are in the floating state (high-impedance state). For example, a voltage of +2.0 V, which is higher than the threshold voltage Vth of the selection transistor 12, is applied to the selected word line WL as the voltage Vreadg. Since the selection transistor 12 is a n-channel MOSFET, the selection transistor 12 is turned on, and the voltage of 0 V (ground voltage) applied to the source line SL is also applied to the lower electrode 13 of the variable resistance element 11 through the selection transistor 12. At the same time, the read voltage Vread (for example, 0.1 V) applied to the selected bit line BL is also applied to the higher electrode 15 of the variable resistance element 11. As a result, read current according to the resistance state of the variable resistance element 11 flows from the selected bit line BL to the selected source line SL. By detecting such read current, the operation for reading the resistance state of the variable resistance element 11, that is, data stored in the memory cell 10, may be performed.

Novel characteristics of the variable resistance element 11, which are the bases of the present invention, will be described in detail hereinafter with reference to the drawings.

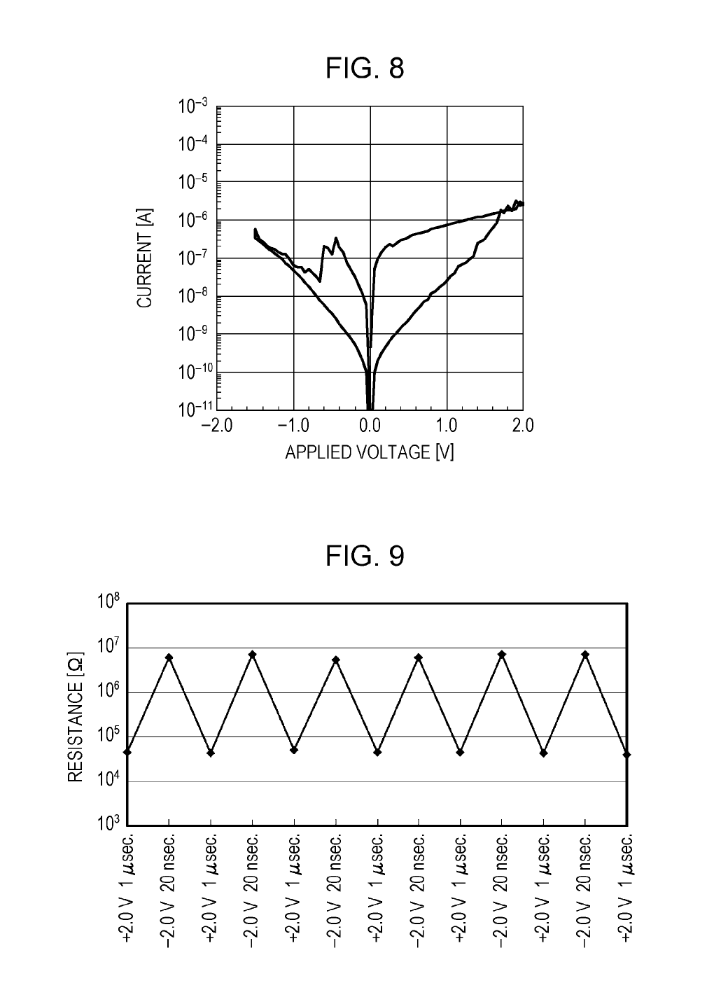

FIGS. 8 and 9 are graphs illustrating the switching characteristics (rewriting characteristics) of the electrical resistance of a variable resistance element 11 that includes a variable resistor 14 composed of a hafnium oxide (HfOx) as an example of the variable resistance element 11.

FIG. 8 illustrates the switching characteristics (rewriting characteristics) of the electrical resistance during application of direct current (DC) voltage. In the first rewriting operation (setting operation), in which the electrical resistance of the variable resistance element 11 changes from the high-resistance state to the low-resistance state, drive current for the selection transistor 12 is limited to 40 μA, and the DC voltage is applied while changing the DC voltage from 0 V to +2.0 V and then from +2.0 V to 0V (double sweep method). On the other hand, in the second rewriting operation (reset operation), in which the electrical resistance of the variable resistance element 11 changes from the low-resistance state to the high-resistance state, the gate of the selection transistor 12 is fully opened, and the DC voltage is applied while changing the DC voltage between 0 V and −1.5 V using the double sweep method.

FIG. 9 illustrates the switching characteristics (rewriting characteristics) of the electrical resistance during application of pulse voltage. In FIG. 9, in the first rewriting operation (setting operation), the drive current for the selection transistor 12 is limited to 40 μA, and first rewriting voltage pulses of +2.0 V are applied for 1 μs. On the other hand, in the second rewriting operation (reset operation), the gate of the selection transistor 12 is fully opened, and second rewriting voltage pulses of −2.0 V are applied for 20 ns.

In the examples illustrated in FIGS. 8 and 9, when a positive first voltage relative to the voltage of the lower electrode 13 is applied to the higher electrode 15, the electrical resistance of the variable resistance element 11 changes from the high-resistance state (first state) to the low-resistance state (second state), and when a negative second voltage relative to the voltage of the lower electrode 13 is applied to the higher electrode 15, the electrical resistance of the variable resistance element 11 changes from the low-resistance state to the high-resistance state. It can therefore be seen that by repeatedly changing the polarity of the rewriting voltage applied to both ends of the variable resistance element 11, the electrical resistance of the variable resistance element 11 continuously switches between the low-resistance state and the high-resistance state. As a result of these changes in the resistance state, binary data (0 and 1) may be stored in the variable resistance element 11 and the storage state may be rewritten.

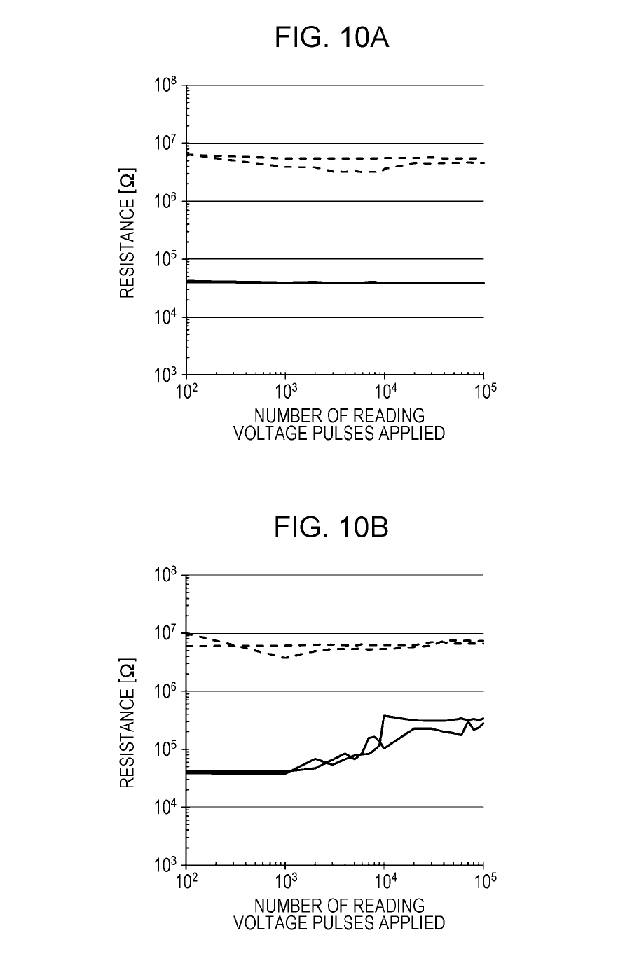

FIGS. 10A and 10B illustrate the disturbance characteristics of a 8-bit variable resistance element 11 during the reading operation in the low-resistance state and the high-resistance state, the variable resistance element 11 having been subjected to the first rewriting operation and the second rewriting operation illustrated in FIG. 9 alternately performed to continuously change the resistance thereof. In the reading operation, negative or positive voltage pulses of 0.5 V are applied for 100 ns.

FIG. 10A is a graph illustrating the number of reading voltage pulses applied and changes in the resistance of the variable resistance element 11 at a time when the reading voltage pulses having the same polarity as the first rewriting voltage pulses in the first rewriting operation (setting operation) are continuously applied without applying the first or second rewriting voltage pulses in a state in which the variable resistance element 11 is in the high-resistance state or the low-resistance state. FIG. 10B is a graph illustrating the number of reading voltage pulses applied and changes in the resistance of the variable resistance element 11 at a time when the reading voltage pulses having the same polarity as the first rewriting voltage pulses in the second rewriting operation (reset operation) are continuously applied without applying the first or second rewriting voltage pulses in a state in which the variable resistance element 11 is in the high-resistance state or the low-resistance state.

As illustrated in FIG. 10A, when the polarity of the reading voltage pulses is the same as that of the first rewriting voltage pulses, there are no large changes in the resistance of the variable resistance element 11 even if the reading voltage pulses are continuously applied to the variable resistance element 11 in the high-resistance state or the low-resistance state.

On the other hand, as illustrated in FIG. 10B, when the polarity of the reading voltage pulses is the same as that of the second rewriting voltage pulses, there are no large changes in the resistance of the variable resistance element 11 even if the reading voltage pulses are continuously applied to the variable resistance element 11 in the high-resistance state, but in the case of the low-resistance state, reading disturbances occur in which the resistance of the variable resistance element 11 significantly changes at a certain point of the continuous reading operations from the low-resistance state to the high-resistance state.

Therefore, it is considered that reading disturbances are unlikely to occur when the reading voltage pulses having the same polarity as the first rewriting voltage pulses in the first rewriting operation (setting operation) are applied in the reading operation performed by the device in the present invention.

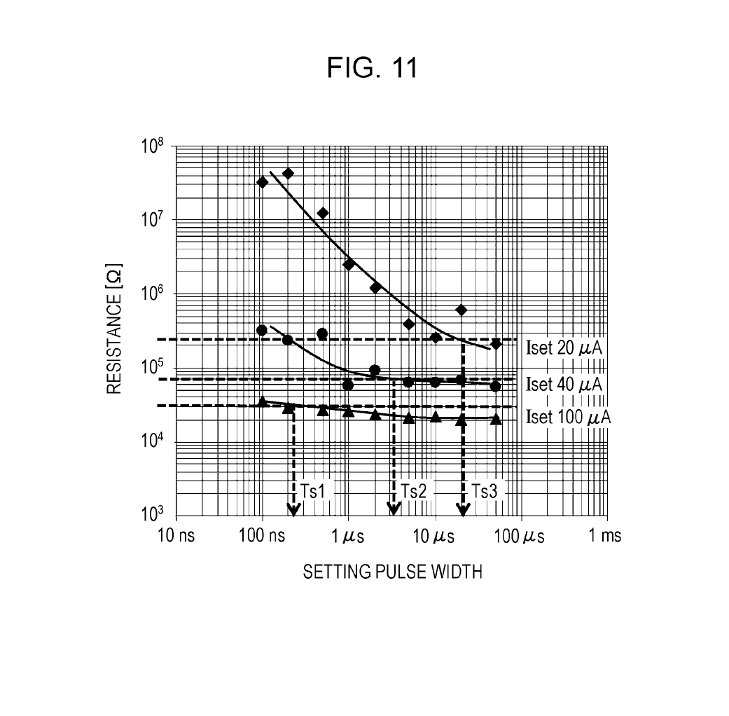

FIG. 11 illustrates a relationship between the resistance of the variable resistance element 11 after a change, the application time of the first rewriting voltage pulses, and the limitation of the amount of current performed by the selection transistor 12 at a time when the voltage Vs applied to the variable resistance element 11 has been fixed (+2.0 V) and the first rewriting operation (setting operation) has been performed. First, the first rewriting voltage pulses are applied for 20 ns, and then adjusted in such a way as to be applied for longer periods. The application time of the pulses illustrated in FIG. 11 is an accumulated time for which the voltage pulses have been applied. 20 μA, 40 μA, and 100 μA are set as the drive current Iset for the selection transistor 12 in the first rewriting operation.

As can be seen from FIG. 11, the smaller the drive current Iset for the selection transistor 12, the longer the application time (pulse width) of the pulses taken to saturate the low-resistance state. Since the low-resistance state of the device in the present invention may be controlled by the driving current Iset for the selection transistor 12, the resistance state is supposed not to depend on the applied pulse width, and times illustrated in FIG. 11 at which the resistance begins to be saturated are pulse widths necessary for the first rewriting operation (setting operation). In FIG. 11, times Ts1, Ts2, and Ts3 are setting pulse widths necessary when the drive current Iset is 100 μA, 40 μA, and 20 μA, respectively.

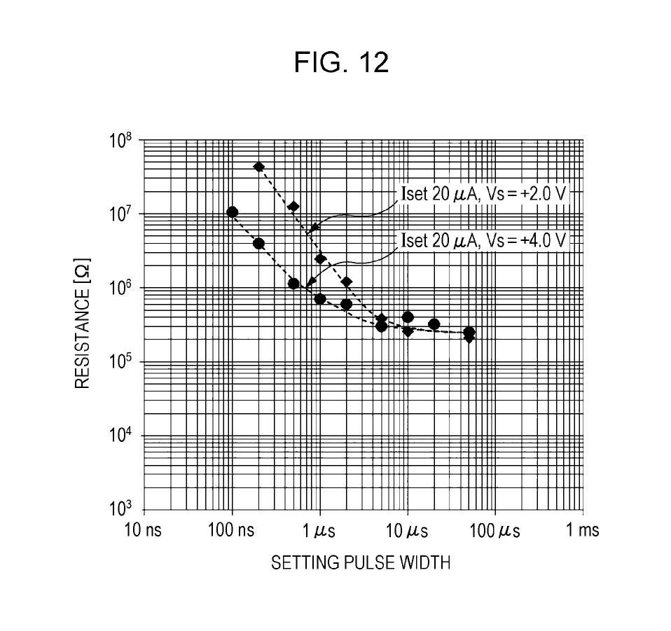

FIG. 12 illustrates a relationship between the resistance of the variable resistance element 11 after a change, the voltage Vs of the applied first rewriting voltage pulses, and the application time at a time when the drive current Iset for the selection transistor 12 has been set to 20 μA and the first rewriting operation (setting operation) has been performed on the variable resistance element 11 on which the first rewriting operation and the second rewriting operation have been alternately performed to continuously change the resistance of the variable resistance element 11. As in FIG. 11, first, the first rewriting voltage pulses are applied for 20 ns, and then adjusted in such a way as to be applied for longer periods. The application time of the pulses illustrated in FIG. 12 is an accumulated time for which the voltage pulses have been applied.

As can be seen from FIG. 12, the application time at which the resistance begins to be saturated after the first rewriting operation remains substantially the same even if the voltage of the applied first rewriting voltage pulses changes. In other words, the absolute value of the voltage of the applied first rewriting voltage pulses may be smaller than the absolute value of the voltage of the applied second rewriting voltage pulses through the limitation of the amount of current performed by the selection transistor 12.

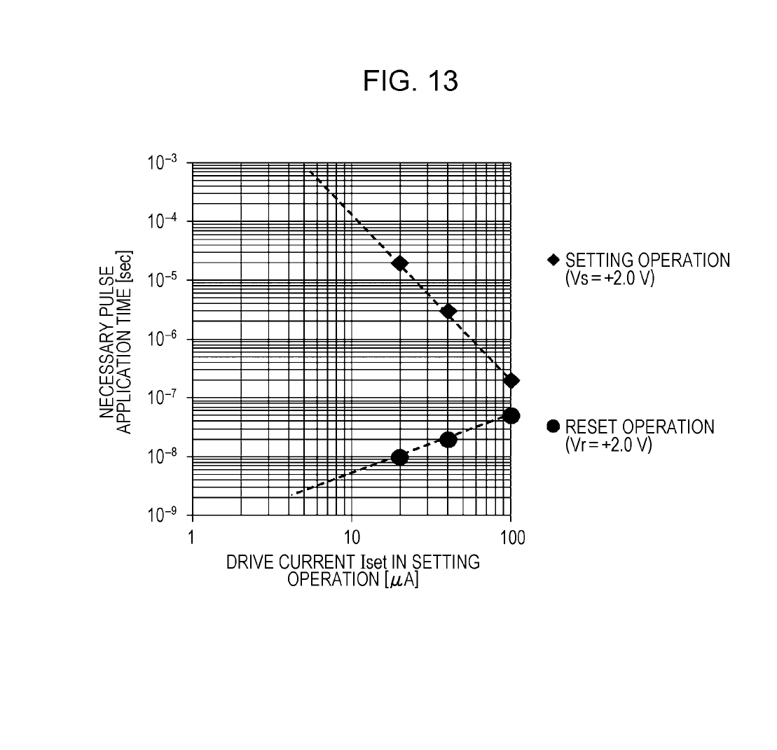

FIG. 13 illustrates a relationship between the drive current Iset for the selection transistor 12 in the first rewriting operation (setting operation) and the application times of the pulses necessary for the first rewriting operation (setting operation) and the second rewriting operation (reset operation) at a time when the absolute values of the applied first and second rewriting voltage pulses are the same (2.0 V). The times Ts1 to Ts3 illustrated in FIG. 11 are plotted as the relationship between the drive current Iset and the application time of the pulses necessary for the first rewriting operation. With respect to the relationship between the drive current Iset and the application time of the pulses necessary for the second rewriting operation, shortest application times of the pulses taken for the resistance to reach a lower limit (here, 10⁶Ω) of the resistance range of the high-resistance state are plotted. As the drive current Iset for the selection transistor 12 becomes smaller, the application time of the pulses necessary for the second rewriting operation (reset operation) becomes shorter in a linear manner. On the other hand, the application time of the pulses necessary for the first rewriting operation (setting operation) becomes larger as a power function. Therefore, the application time of the pulses necessary for the first rewriting operation (setting operation) becomes necessarily longer than the application time of the pulses necessary for the second rewriting operation (reset operation).

Therefore, the device in the present invention may avoid accidental erasure (reading disturbances) of stored data by performing the reading operation using reading voltage pulses whose polarity is the same as that of the voltage pulses applied in the first rewriting operation, in which the application time of the pulses is longer than that of the pulses applied in the second rewriting operation, even if the reading operation has been repeatedly performed on the same memory cell 10. Accordingly, data retention characteristics may be significantly improved.

### Other Embodiments

Other embodiments will be described hereinafter.

<1> Although the source lines SL in the memory cell array 20 extend in the row direction, that is, in a direction perpendicular to the bit lines BL, in the configuration of the device in the present invention, the source lines SL in the memory cell array 20 may extend in the column direction, that is, in a direction parallel to the bit lines BL, instead. In the present invention, the configuration of the memory cell array 20 is not limited to the circuit configuration illustrated in FIG. 2. The memory cell array 20 may be configured by connecting the memory cells 10 including the variable resistance element 11 to one another using the word lines WL and the bit lines BL, and the device in the present invention is not limited by the specific circuit configuration of the memory cell array 20. The selection transistor 12 need not be provided for each memory cell 10, and because the amount of current flowing through the variable resistance elements 11 in the first rewriting operation may be limited by the transistors provided in the column decoder 21 and connected to the bit lines BL, the present invention may be applied to a memory cell array of a single-resistance (1R) type.

Although the source lines SL extend in the row direction parallel to the word lines WL1 to WLm and two adjacent rows share the same source line SL connected to the common line CML outside the memory cell array 20 in FIG. 2, a source line SL may be provided for each row, or the source lines SL may extend not in the row direction but in the column direction, instead. Furthermore, as with the word lines WL and the bit lines BL, the source lines SL may be configured in a selectable manner so that a memory cell 10 or a memory cell group including a plurality of memory cells 10 may be selected, instead. In addition, although the one terminals of the memory cells 10 on the side of the variable resistance elements 11 are connected to the bit lines BL and the other terminals of the memory cells 10 on the side of the selection transistors 12 are connected to the source lines SL in FIG. 2, the one terminals of the memory cells 10 on the side of the variable resistance elements 11 may be connected to the source lines SL and the other terminals of the memory cells 10 on the side of the selection transistors 12 may be connected to the bit lines BL, instead.

<2> In the device in the present invention, since the selection transistor 12 limits the amount of current and the first rewriting operation (setting operation) is performed using small current, an application time of the pulses of about 1 is needed for the first rewriting operation, which makes it difficult for the device in the present invention to operate at high speed. Therefore, a method for reducing the application time of the pulses necessary for the first rewriting operation performed on each memory cell 10 may be used in which a plurality of memory cells 10 are selected and the first rewriting operation is collectively performed on the plurality of memory cells 10.

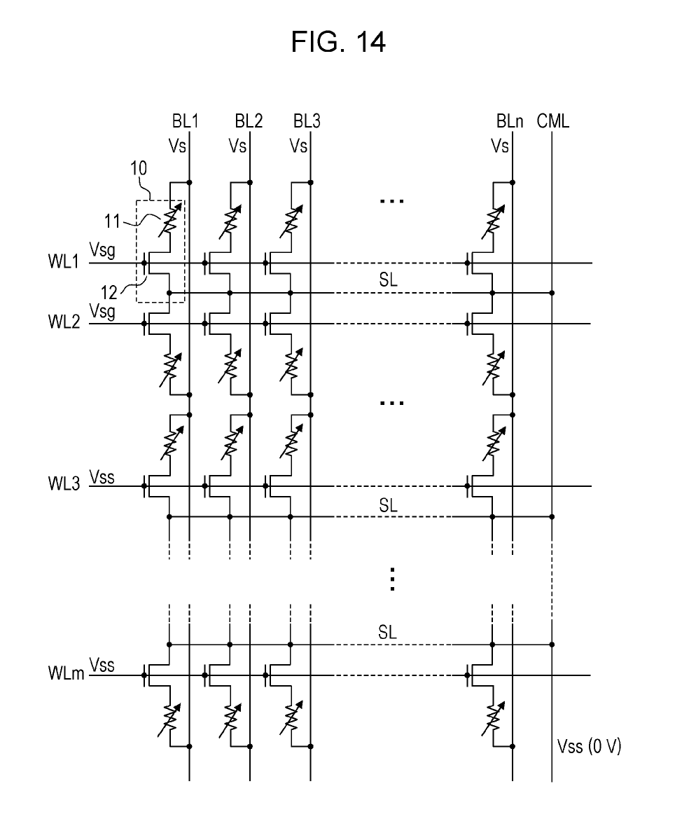

For example, FIG. 14 illustrates application of voltages to a plurality of memory cells 10 at a time when the first rewriting operation (setting operation) is simultaneously performed on the plurality of memory cells 10 in a row or in a plurality of rows. One or a plurality of word lines (here, the word lines WL1 and WL2) corresponding to the target row(s) are selected, and the selected word line voltage Vsg is applied only to the selected word lines WL1 and WL2. By applying a voltage of 0 V (ground voltage Vss) to other word lines WL that have not been selected, the selection transistors 12 of the selected memory cells 10 connected to the selected word lines WL1 and WL2 are turned on. On the other hand, for example, a voltage of 0 V (ground voltage Vss) is applied to all the source lines SL, and a voltage of +2.0 V is applied to all the bit lines BL as the voltage Vs. When a plurality of word lines WL are to be arbitrarily selected, a function of arbitrarily selecting a plurality of word lines WL may be added to the row decoder 22.

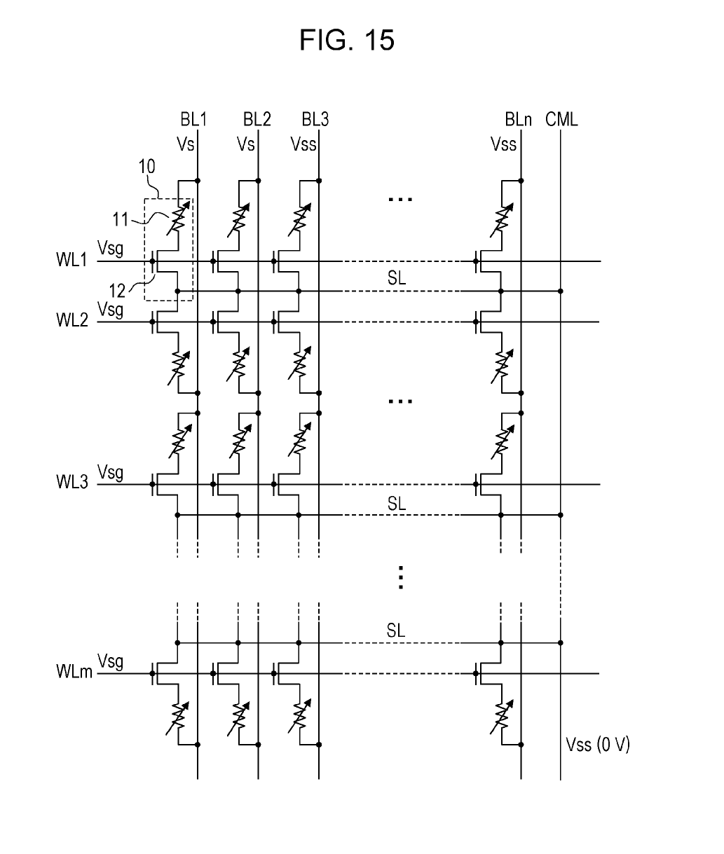

Alternatively, when the first rewriting operation (setting operation) is to be performed on a plurality of memory cells 10 in a column or in a plurality of columns, all the word lines WL are selected and the voltage Vsg is applied to all the word lines WL as illustrated in FIG. 15. Meanwhile, one or a plurality of bit lines (here, the bit lines BL1 and BL2) corresponding to the target column(s) are selected and the voltage Vs is applied to the selected bit lines BL1 and BL2 while applying a voltage of 0 V (ground voltage Vss) to other bit lines BL that have not been selected or establishing the floating state (high-impedance state) in the other bit lines BL. When a plurality of bit lines BL are to be arbitrarily selected, a function of arbitrarily selecting a plurality of bit lines BL may be added to the column decoder 21.

Furthermore, when the first rewriting operation (setting operation) is to be simultaneously performed on a plurality of memory cells 10 in a row and a column or in a plurality of rows and columns, one or a plurality of word lines WL corresponding to the target row(s) are selected and the selected word line voltage Vsg is applied only to the selected word lines WL in the same manner as above while a voltage of 0 V (ground voltage Vss) is applied to other word lines WL that have not been selected. Meanwhile, one or a plurality of bit lines BL corresponding to the target column(s) are selected and the voltage Vs is applied to the selected bit lines Vs while applying a voltage of 0 V (ground voltage Vss) to other bit lines BL that have not been selected or establishing the floating state (high-impedance state) in the other bit lines BL.

<3> Although the first rewriting operation (setting operation) is performed by applying positive voltage pulses relative to the voltage of the source line SL between both terminals of a selected memory cell 10 and the second rewriting operation (reset operation) is performed by applying negative voltage pulses relative to the voltage of source line SL between both terminals of the selected memory cell 10 in the above embodiment, this relationship is reversed depending on the configuration of the variable resistance element 11. That is, a configuration may be adopted in which the first rewriting operation (setting operation) is performed by applying negative voltage pulses relative to the voltage of the source line SL between both terminals of the selected memory cell 10 and the second rewriting operation (reset operation) is performed by applying positive voltage pulses relative to the source line SL between both terminals of the selected memory cell 10.

<4> The voltage values used in the above embodiment are merely examples, and the conditions of applied voltages and the threshold voltage used in the device in the present invention are not limited to such voltage values.

The present invention may be applied to a semiconductor storage device and, more particularly, may be applied to a non-volatile semiconductor storage device including variable resistance elements whose resistance states change in accordance with application of voltage and that hold information in accordance with the resistance states after the change.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A semiconductor storage device comprising:
a variable resistance element that is used for storing information and that includes a variable resistor composed of a metal oxide or a metal oxynitride and a first electrode and a second electrode that sandwich the variable resistor, electrical resistance between both electrodes of the variable resistance element changing in accordance with electrical stress applied between both electrodes,
wherein, in a first rewriting operation in which a resistance state of the variable resistance element is changed from a first state to a second state, which is a low-resistance state, a first voltage pulse whose absolute value of voltage amplitude is a first voltage and that has a first polarity is applied to both terminals of a memory cell including the variable resistance element,
wherein, in a second rewriting operation in which the resistance state of the variable resistance element is changed from the second state to the first state, which is a high-resistance state, a second voltage pulse whose absolute value of voltage amplitude is a second voltage, that has a second polarity, which is opposite the first polarity, and whose application time is shorter than application time of the first voltage pulse is applied to both terminals of the memory cell, and
wherein, in a reading operation in which the resistance state stored in the variable resistance element is read, a third voltage pulse that has the first polarity and whose absolute value of voltage amplitude is smaller than the absolute value of the voltage amplitude of the first voltage is applied to both terminals of the memory cell.

2. The semiconductor storage device according to claim 1,
wherein, in the first rewriting operation, the first voltage pulse is applied to both terminals of the memory cell while limiting an amount of current flowing through the variable resistance element to a value smaller than or equal to a certain small amount of current, and,
wherein, in the second rewriting operation, the second voltage pulse is applied to both terminals of the memory cell while allowing an amount of current larger than the certain small amount of current to flow into the variable resistance element.

3. The semiconductor storage device according to claim 2,
wherein the certain amount small current is smaller than or equal to 100 μA.

4. The semiconductor storage device according to claim 1,
wherein the second voltage is a voltage equal to or higher than the first voltage.

5. The semiconductor storage device according to claim 4,
wherein the second voltage is the same as the first voltage.

6. The semiconductor storage device according to claim 1,
wherein the memory cell is configured by connecting either the first electrode or the second electrode of the variable resistance element and one terminal of a pair of input and output terminals of a selection transistor to each other,
the semiconductor storage device further comprising:
a memory cell array that includes a plurality of memory cells, each of which is the foregoing memory cell, are arranged at least in a row direction or in a column direction;
a control circuit that selects one or a plurality of memory cells from the memory cell array and that controls the first rewriting operation, the second rewriting operation, and the reading operation performed on a variable resistance element of the selected one or plurality of memory cells; and
a voltage application circuit that applies necessary voltages to both terminals of the selected one or plurality of memory cells and a control terminal of the selection transistor of the selected one or plurality of memory cells in the first rewriting operation, the second rewriting operation, and the reading operation.

7. The semiconductor storage device according to claim 6,
wherein, in the first rewriting operation, the voltage application circuit applies a voltage higher than ground voltage by the first voltage to one terminal of the selected one or plurality of memory cells and the ground voltage to the other terminal, and
wherein, in the second rewriting operation, the voltage application circuit applies the ground voltage to the one terminal of the selected one or plurality of memory cells and a voltage higher than the ground voltage by the second voltage to the other terminal.

8. The semiconductor storage device according to claim 6,
wherein, in the memory cell array, one terminals of memory cells in the same column on a side of variable resistance elements are connected to a bit line extending in the column direction,
wherein control terminals of the selection transistors of memory cells in the same row are connected to a word line extending in the row direction,
wherein the other terminals of the memory cells on a side of the selection transistors are connected to a source line extending in the row direction or the column direction,
wherein the first voltage pulse is a positive voltage pulse relative to voltage of the source line connected to the selected one or plurality of memory cells, and
wherein the second voltage pulse is a negative voltage pulse relative to the voltage of the source line connected to the selected one or plurality of memory cells.

9. The semiconductor storage device according to claim 6,
wherein the selection transistors are n-channel metal-oxide-semiconductor field-effect transistors.
